(19) United States
(12) Patent Application Publication
(10) Pub. No.: US 2024/0220690 A1
(43) Pub. Date: Jul. 4, 2024

(54) Synthesis and Verification of an Integrated Circuit (IC)

(71) Applicant: RapidSilicon US, Inc, Los Gatos, CA (US)

(72) Inventor: Thierry Besson, Antibes (FR)

(21) Appl. No.: 18/091,755

(22) Filed: Dec. 30, 2022

(51) Int. Cl. G06F 30/327; G06F 30/3323

(52) U.S. Cl. CPC G06F 30/327; G06F 30/3323

(57) ABSTRACT

A technology is described for designing an integrated circuit (IC) by incrementally and concurrently synthesizing and formally verifying a plurality of intermediate netlists. The intermediate netlists are synthesized from a register transfer level (RTL) description of the IC. Synthesizing intermediate netlists is continued while the formal verification processes execute concurrently with the synthesizing. An indication of validity or non-validity of the intermediate netlists is from the formal verification process. The RTL description is proven to be formally equivalent to a final netlist formed of the intermediate netlists by proving that the all the intermediate netlists are valid.

### BACKGROUND

A semiconductor or integrated circuit (IC) has electronic circuits formed on semi-conductors such as silicon. Some ICs can be programmable logic devices (PLD) with reconfigurable digital circuits having an undefined function at the time of manufacture. The PLD can be field-programmable gate arrays (FPGAs) designed to be configured by a customer or a designer after manufacturing.

Over the past few decades, FPGAs have established themselves as a dominant player in the digital design landscape thanks to a flexibility and cost-effectiveness not achievable by semi-custom circuits. However, this comes at a performance, power consumption, and area utilization trade-off, and so, highly efficient design implementations are desired in order to balance out these accommodations. In particular, logic synthesis which translates Register-Transfer-Level (RTL) design descriptions into gate-level implementations is a step that profoundly impacts the performance of the resulting circuit. This may even be truer in the context of FPGAs, where optimizing the gate-level implementation of a design has a strong impact on both area (in terms of LUT resource utilization) and performance (in terms of maximum frequency).

Logic synthesis may broadly be divided into two steps: technology independent, which optimizes the logic of a design, and technology dependent, which maps that logic onto a library of primitives while optimizing the mapping for some cost function. Technology independent optimization typically consists of transforming the RTL into a homogeneous Directed Acyclic Graph (DAG) and manipulating this graph towards a given optimal target using a sequence of transformations.

### BRIEF DESCRIPTION OF THE DRAWINGS

FIG. 1a is a diagram illustrating an example of concurrent register transfer level (RTL) synthesis and formal verification flow of intermediate netlists.

FIG. 1b is a schematic illustrating an example of a synthesis engine and a formal verification engine for implementing the synthesis and formal verification.

FIG. 2 is a flowchart illustrating an example of a method of designing an IC with concurrent synthesis and formal verification of intermediate netlists.

FIG. 3 is a flowchart illustrating an example of a method of designing an IC with formal verification of different intermediate netlists processing in-parallel.

FIG. 4 is a flowchart illustrating an example of a method of designing an IC including modifying the RTL description of a non-valid intermediate netlist.

FIG. 5 is a flowchart illustrating an example of a method of designing an IC including pausing synthesis of intermediate netlists while awaiting formal verification.

FIG. 6 is a flowchart illustrating an example of a method of designing an IC including performing formal verification of an intermediate netlist using two different formal verification engines in parallel.

FIG. 7 is a flowchart illustrating an example of a method of designing an IC including a second formal varication process using simulation-based verification.

FIG. 8 is a flowchart illustrating an example of a method of designing an IC with concurrent synthesis and formal verification of intermediate netlists.

FIG. 9 is a block diagram of an example of a service provider environment or cloud environment upon which the technology may be executed.

FIG. 10 is a block diagram that provides an example illustration of a computing device that can be employed in the present technology.

### DETAILED DESCRIPTION

Reference will now be made to the examples illustrated in the drawings, and specific language will be used herein to describe the same. It will nevertheless be understood that no limitation of the scope of the technology is thereby intended. Alterations and further modifications of the features illustrated herein, and additional applications of the examples as illustrated herein, which would occur to one skilled in the relevant art and having possession of this disclosure, are to be considered within the scope of the description.

The previously existing approach for designing an integrated circuit (IC) involves performing RTL synthesis followed by formal verification. Formal verification involves proving that the RTL is the functional equivalent the synthesized netlist. Thus, two separated steps are performed sequentially, and are generally addressed by two different human engineering groups in a company: a synthesis group of engineers and a design verification group of engineers. The previously existing approach of synthesizing an RTL description and validating the functional correctness of the resulting netlist has been done in two separated and consecutive steps. These two steps are usually separated in time (e.g., hours or days) and are also usually separated by using different engineers to perform each step. First, the synthesis of the RTL description is performed by the synthesis team to obtain the post synthesis netlist, which is then is given to the verification team. Second, a formal verification flow between the original RTL description and the synthesized netlist is applied by the verification team to see if the netlist is functionally correct as compared to the original RTL description.

In some cases, formal verification does not work, and the verification team will use simulation-based techniques or report the issue back to the synthesis team. When formal verification fails, the synthesis may be run with special options to help the formal verification team. Typically, some hints are given to the formal verification tool, such as some naming conventions. Some specific net names in the final netlist can also be recognized by the formal verification tool and used to ease the verification. Naming conventions can be defined between the synthesis team and the team using the formal verification tool (e.g. OneSpin® and Formality®).

Therefore, there are two separate and sequential workflows used to synthesize an RTL design and verify that the synthesis is functionally correct for the design. Often, different teams handle the different processes, which can generate inefficiencies, such as back-and-forth discussions, multiple tries, misunderstandings, etc. The synthesis team may not have expertise about the formal verification, and the verification team may not have expertise about the synthesis. The formal verification is performed after design synthesis and may sometimes fail. The verification team may need to determine how to fix the verification and/or may report back to the synthesis team regarding the issues. Verification can take 70% of the whole process time. Thus, verification can be more time consuming than actually synthesizing the design.

Separately performing design synthesis and formal verification, as presently performed, leads to many difficulties and inefficiencies. The present technology provides a framework where synthesis and formal verification are performed simultaneously and/or are interleaved so that synthesis and formal verification work together. The system can include an integrated verification and synthesis system that takes an already verified design from RTL to gate-level implementation and incrementally checks gate-to-gate improvements.

In one aspect, both synthesis and formal verification are performed automatically using a single request interface. Thus, the RTL designer, who may not be an expert in formal verification, will be given: 1) confirmation of the logical correctness of the synthesized netlist as compared to the RTL description or a previous netlist, or 2) an early warning on the difficulty to prove the correctness of the synthesized netlist. If the netlist fails verification, then the RTL designer knows immediately that validating the netlist will be difficult and is given an early opportunity to implement settings and/or fixes, such as varying the formal verification options to use in the synthesis command(s).

The present technology resists failed verification by providing intermediate netlists, between the original RTL description and the final netlist. It may be difficult, in some cases, to directly compare the original RTL description and the final netlists because there may be too many changes and/or optimizations in between, such as “retiming.” The formal verification tool may not be able to determine how to prove a netlist, and thus fails. Using an incremental verification approach, by verifying intermediate netlists from the RTL description through to the final netlist, can help to fix the problem by associativity. If the RTL description is proved to be equivalent to an intermediate netlist at step 1, which is equivalent to intermediate netlist at step 2, which is equivalent to intermediate netlist at step N, which is equivalent to the final netlist, then the formal equivalence is proved between the end points (RTL description vs final netlist).

In another aspect, the present technology provides a single “synthesis” command that implements both synthesis and formal verification at the same time. The command can be a single command (e.g., push a single button) entered by the designer to have one or more intermediate synthesized netlist formally proved by a third-party verification tool. Thus, the present synthesis tool has a combined synthesis and formal verification feature. With the combined feature, there is less wasted time understanding the following: why the netlist fails formal verification, why it eventually needs to be resynthesized in a different mode, and/or why the verification may eventually give up and look for an alternative solution, like simulation-based tools.

In another aspect, the present technology can utilize a simulation-based tool when the design fails the formal verification. The simulation-based verification can be implemented to execute automatically, e.g. under the same command. Thus, synthesis, verification and simulation are implemented under a same command. The formal verification tool(s) that may integrate into the synthesis command could be OneSpin® and Formality®. The formal verification tool may be an open-source formal verification tool or a proprietary verification tool.

Synthesis and formal verification of intermediate netlists can be implemented with the present technology to prove the functional correctness of the synthesis. Four synthesis configurations may be used, namely: 1) with block random access memory/digital signal processor (BRAM/DSP) inference, 2) without BRAM/DSP inference, 3) with strong optimization, and 4) without strong optimization. The two options result in four combinations that may have between 99% and 91% formal verification success.

By way of example, the RTL designer can launch the synthesis command (e.g. “synth_rs”) to launch the formal verification flow too. The synthesis command can have options related to the formal verification flow mode. One option can implement formal verification mode (e.g., “-fv” usage implements formal verification at the same time as synthesis). Another option may select which formal verification tool to use (e.g. OneSpin® or Formality®) and the executable path of the formal verification tool. Another option can drive the synthesis in a special formal verification (“-fv”) mode, such as incremental dumps of netlist or no incremental dumps, frequency of the dumps, etc. Another option can set the formal verification tools to use a naming convention or no formal naming convention. The options (except “-fv”) can have default values for ease of use that can cover a majority cases.

Once the synthesis starts, it can dump intermediate netlists at key points in the synthesis flow. Key points can include where major transformations occur, such as “retiming” and strong “optimizations”. The frequency of dumping can be changed by one of the options in the command. For some key synthesis procedures and/or for some specific designs, the frequency of dumping intermediate netlists can occur at a very high rate for the incremental formal verification to work. In some cases, even a very simple change in the netlist due to synthesis transformation can confuse a formal verification tool. Thus, dumping some intermediate netlists may occur at a very high rate.

When the synthesis starts, a verification manager thread (i.e., process) can launch in the background and in parallel with the synthesis that will take care of the formal verification. This process can communicate both with synthesis and formal verification tools to synchronize the two types of tool. Typically, when synthesis is at step ‘i’ and has dumped netlist N(i) at step ‘i’, the verification manager process working in parallel will get a notice from the synthesis tool that N(i) is ready and will launch a formal verification comparing N(i−1) and N(i) by calling a verification tool (e.g. OneSpin® or Formality®). During this time, synthesis continues until reaching milestone ‘i+1’ and dumping netlist N(i+1). So, both synthesis and formal verification can work together and simultaneously with formal verification following the pace of synthesis and with formal verification one step behind synthesis.

In one aspect, multiple formal verifications can run concurrently. For example, verification between N(i−2) and N(i−1) and verification between N(i−1) and N can run at the same time. Thus, formal verification can be implemented faster to keep up with synthesis. In another aspect, multiple formal verification tools can run concurrently or in parallel. For example, verification can run on a first verification tool (e.g. OneSpin®) and on a second verification tool (e.g. Formality®). Thus, one tool may be faster than another.

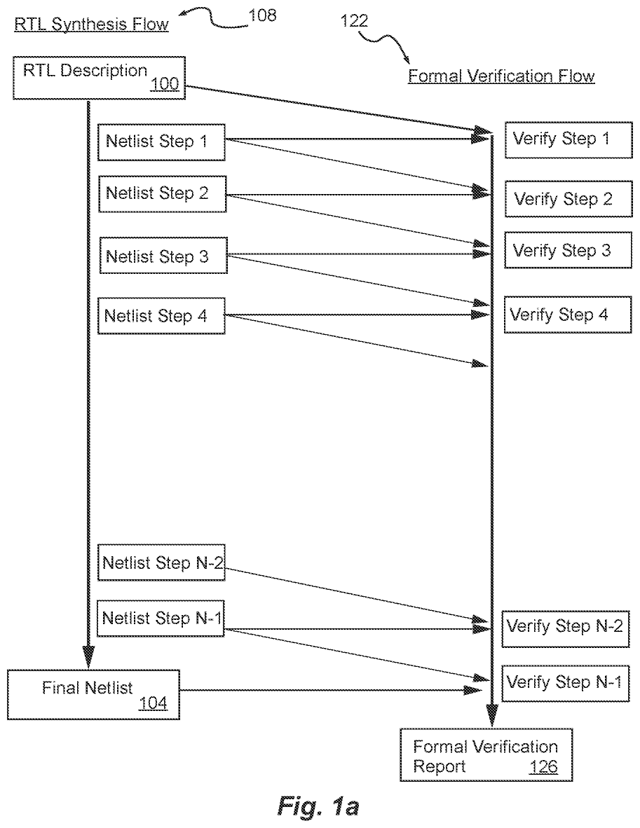

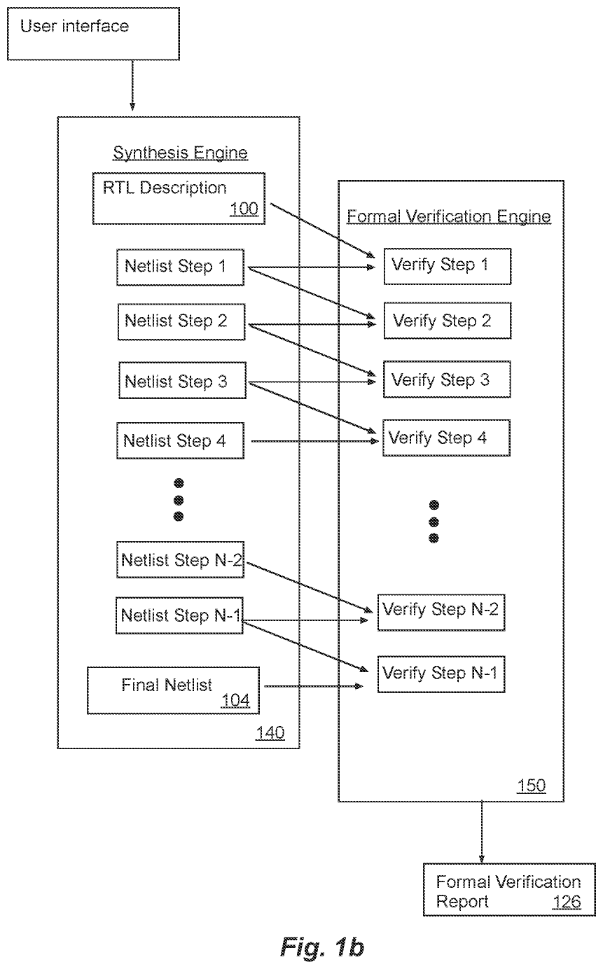

FIG. 1a depicts an example of the flow of the present technology. The flow is a sequence of synthesis (netlist transformations) and incremental formal verifications between these transformations. The present technology proposes to synthesize and formally verify concurrently, as an automatic process. An original RTL description 100 may be synthesized into a final netlist description 104 through a sequence of intermediate synthesis steps (or logic transformations) 108. At the same time, a formal verification 122 is called on each step, between each intermediate netlist, so that at the end of the synthesis flow, both the final netlist is synthesized and the report of the verification 126 is obtained. The report indicates whether or not the RTL description and the final netlist are formally equivalent. Rather than perform the two flows separately and sequentially, they are performed together, concurrently and cooperatively.

As shown in FIG. 1a, two vertical flows may execute in parallel, namely the RTL synthesis flow can drive the formal verification flow. Formal verification 122 can compare two intermediate netlists. For example, “Verify Step 2” can compare intermediate “Netlist Step 1” versus intermediate “Netlist Step 2” for logical equivalence. In addition, “Verify Step 1” task and “Verify Step 2” task (and even other “Verify Step N” task) can run in parallel because these are independent problems. When formal verification is able to prove each of the verification steps (e.g., “Verify Step i” (for i=1 to N−1)), then the RTL description 100 is proved to be formally equivalent to the final netlist 104. Because if the RTL description 100 is formally equivalent to “Netlist Step 1”, which is formally equivalent to “Netlist Step 2”, which is formally equivalent to “Netlist Step 3”, . . . which is formally equivalent to “Netlist Step N−1”, which is formally equivalent to the final netlist 104, then both the RTL description 100 and the final netlist 104 are equivalent by the associativity rule of equivalency.

FIG. 1b depicts an example of the present technology with the synthesis being performed with a synthesis engine 140 or program and the formal verification process being performed with a formal verification engine 150. The synthesis engine 140 and/or the formal verification engine 150 may reside and operate on a local computer, remote server or cloud network. The server may be hosted on a private cloud, a public cloud or in a data center.

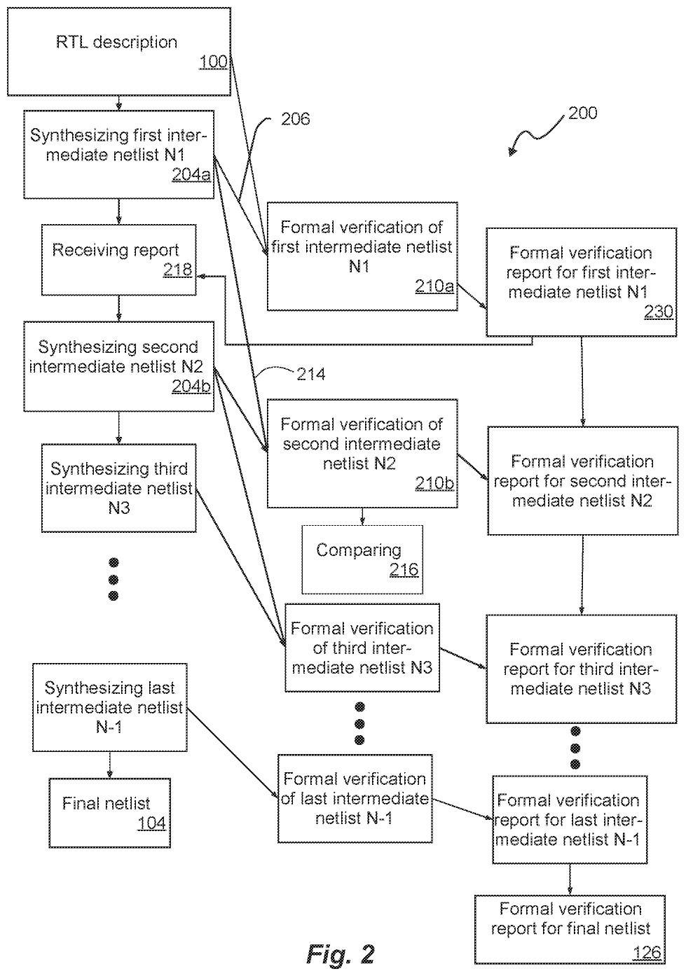

FIG. 2 depicts an example of a method 200 of designing an IC with concurrent synthesis and formal verification of intermediate netlists. The method 200 comprises synthesizing 204a and 204b a plurality of intermediate netlists sequentially from a register transfer level (RTL) description 100 of the IC. The intermediate netlists are multiple netlists that are intermediate versions of the RTL description 100. The intermediate netlists can be created by the application of different transformations comprising at least one of: retiming or optimizations. In one aspect, the synthesizing 204a and 204b can be performed with a synthesis engine 140 (FIG. 1b). The synthesis engine 140 may reside and operate on a local computer, remote server or cloud network. The server may be hosted on a private cloud, a public cloud or in a data center.

The method 200 also includes launching 206 formal verification processes 210a and 210b for the plurality of intermediate netlists incrementally and concurrently with the synthesizing 204a and 204b. In one aspect, the formal verification processes 204a and 204b can be performed with a formal verification engine 150 (FIG. 1b) or program. The formal verification engine may reside and operate on a local computer, remote server or cloud network. The server may be hosted on a private cloud, a public cloud or in a data center. When separate synthesis or verification processes are launched, the verification process may be executed independently in the cloud, as managed by a cloud execution manager or cloud scheduler.

In another aspect, the synthesizing 204a and 204b and the formal verification processes 210a and 210b can be performed by a separate synthesis engine and formal verification engine 140 and 150 as shown in FIG. 1b. Thus, different parties with different expertise can provide the different engines. In another aspect, the synthesis engine 140 (or a synthesis suite) can launch 206 the formal verification processes 210a and 210b for the formal verification engine 150. Thus, the designer can instigate the formal verification process 210a and 210b while synthesizing 204a and 204b. Meanwhile, the method includes continuing synthesizing 204a and 204b the plurality of intermediate netlists while the formal verification processes 210a and 210b execute concurrently with the synthesizing operations 204a and 204b. The intermediate netlists can be sent sequentially by the designer and/or the synthesis engine from the synthesis engine to the formal verification engine.

For example, synthesizing the plurality of intermediate netlists sequentially can comprise synthesizing 204a a first intermediate netlist. Launching the formal verification processes can comprise launching 206 a formal verification process 210a for the first intermediate netlist as compared to the RTL description 100. A second intermediate netlist can be synthesized 204b while the formal verification process 210a executes concurrently for the first intermediate netlist. Thus, synthesizing and launching formal verification processes can comprise synthesizing 204a a first intermediate netlist and launching 206 a formal verification process 210a for the first intermediate netlist concurrently while synthesizing 204b the second intermediate netlist 210b.

Each formal verification process 210a and 210b can be launched 206 by entering a command to the synthesis engine 140 where synthesizing 204a and 204b is performed to launch 206 the formal verification process 210a and 210b for the intermediate netlist to begin. In one aspect, the formal verification process 210a and 210b may occur automatically. The command and/or the launch 206 can comprise specifying formal verification parameters for the formal verification processes 210a and 210b and/or the formal verification engine 150, such as: mode of formal verification or not formal verification; a selection of a formal verification engine; incremental dumps of intermediate netlists; frequency of dumps of intermediate netlists; and/or use of naming conventions.

Launching 206 the formal verification processes 210a and 210b can further comprise launching 214 a formal verification process 210b for a subsequent intermediate netlist and comparing 216 the subsequent intermediate netlist with a prior intermediate netlist 214 (e.g., comparing netlist 2 with netlist 1).

In addition, the method 200 can include receiving 218 an indication of validity or non-validity of the plurality of intermediate netlists from the formal verification process 210a. The verification processes 210a can determine that the synthesis of the intermediate netlists are valid or non-valid. For valid netlists, the RTL description 100, or portion thereof, is proved to be formally equivalent to the corresponding intermediate netlist by the formal verification processes 210a and 210b. For non-valid, the RTL description 100 is not proved to be formally equivalent to the corresponding intermediate netlist, and/or is incapable of being proven by the formal verification process 210a and 210b. In one aspect, the indications can be visually displayed, such as on a monitor, and viewed by the designer. In another aspect, the indications can be received by the synthesis engine 140 and written to a log file. The designer and/or the synthesis engine 140 may utilize the indication(s) in determining whether or not to proceed, and/or how to proceed, with the synthesis 204a and 204b. In another aspect, the indications can be accumulated to form the formal verification report 126 for the final or entire netlist 104.

To summarize, the RTL description 100 can be proved as formally equivalent to the final netlist 104 by proving that the all the intermediate netlists are valid, as described above.

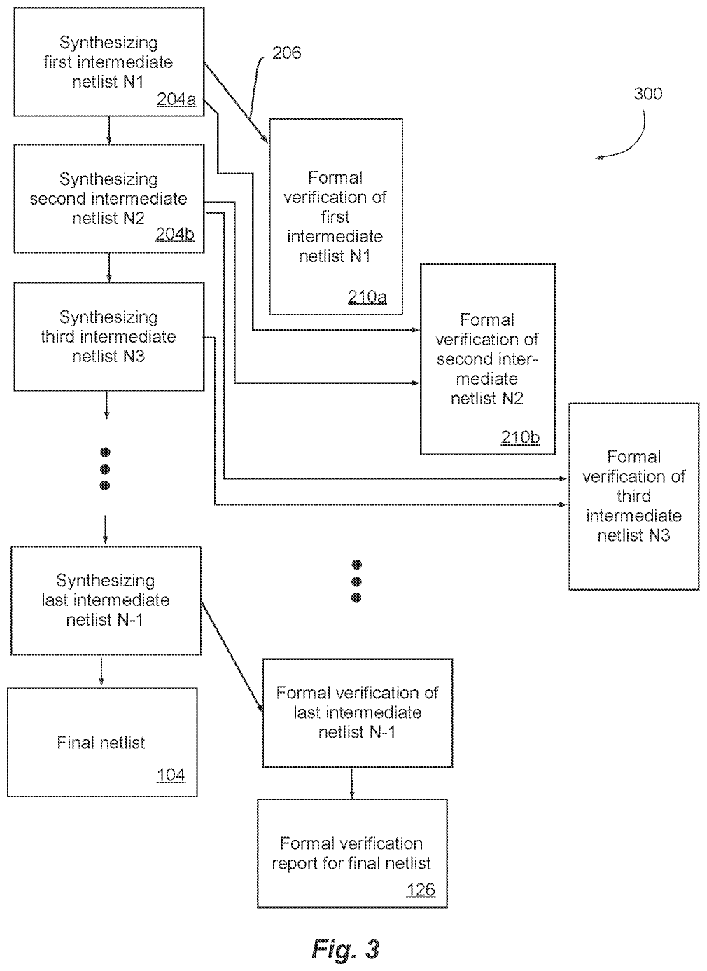

FIG. 3 further depicts an example of the method 300 where launching 206 the formal verification processes 210a and 210b can further comprise launching 206 formal verification processes 210a and 210b for at least two separate intermediate netlists in parallel. Thus, multiple intermediate netlists can be validated and proceed with the formal verification processes 210a and 210b at the same time for efficient synthesis and verification.

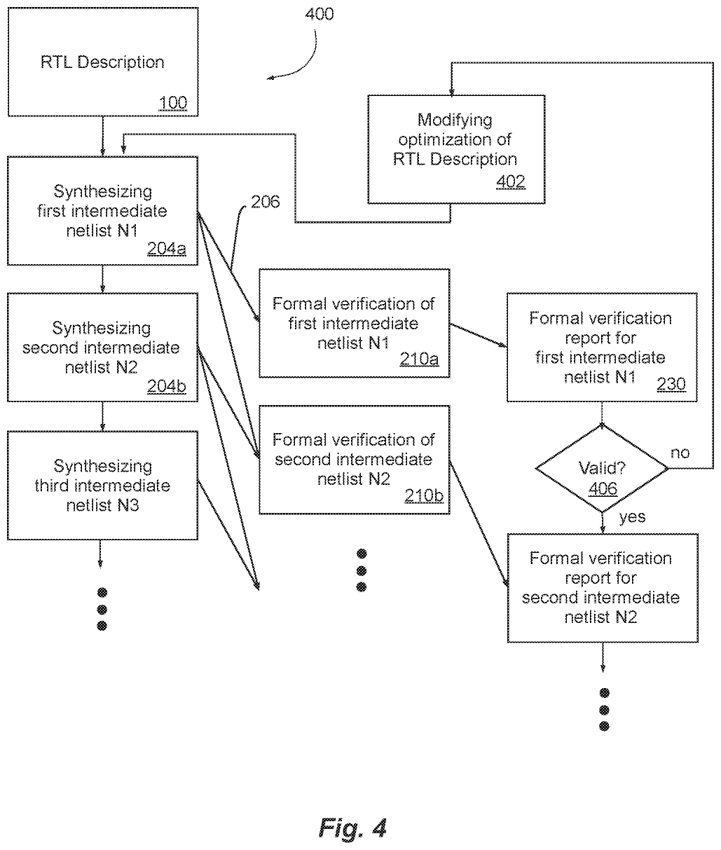

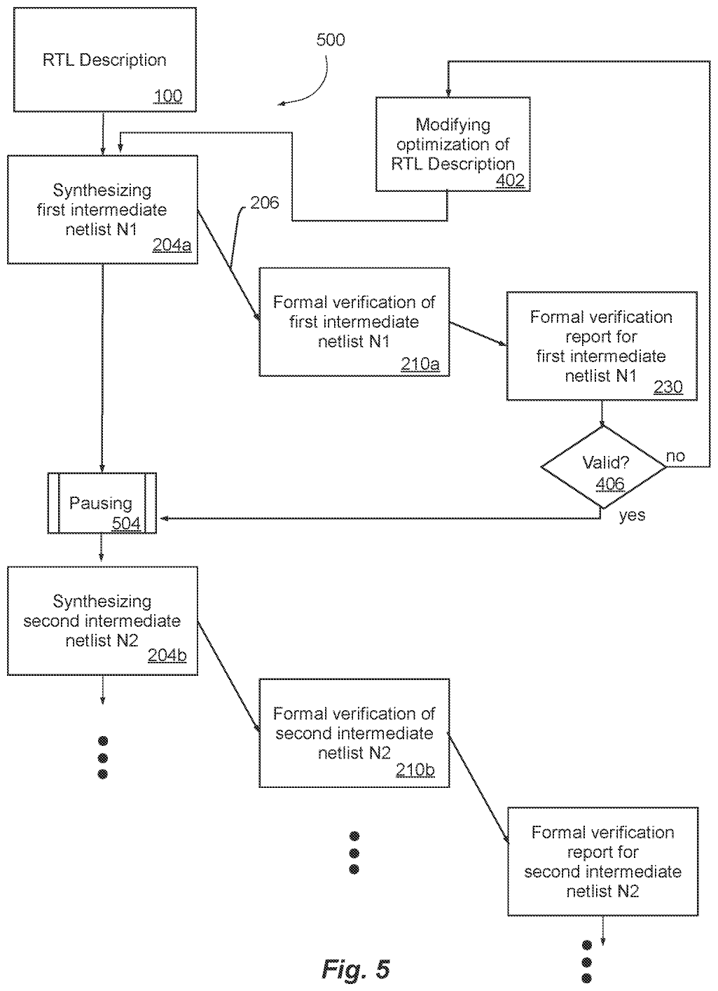

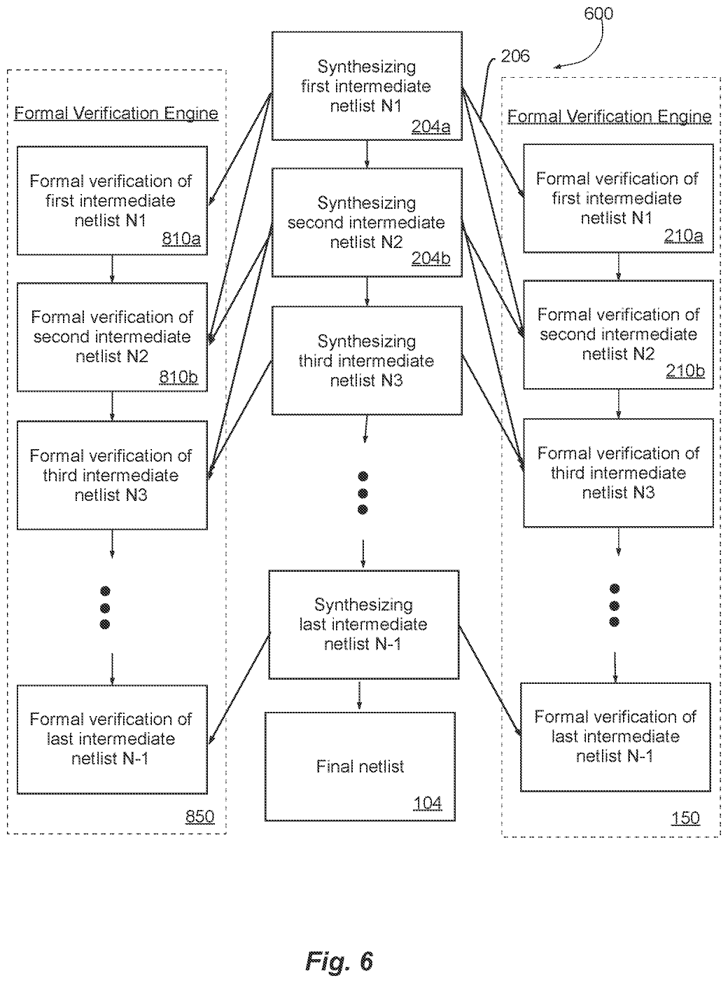

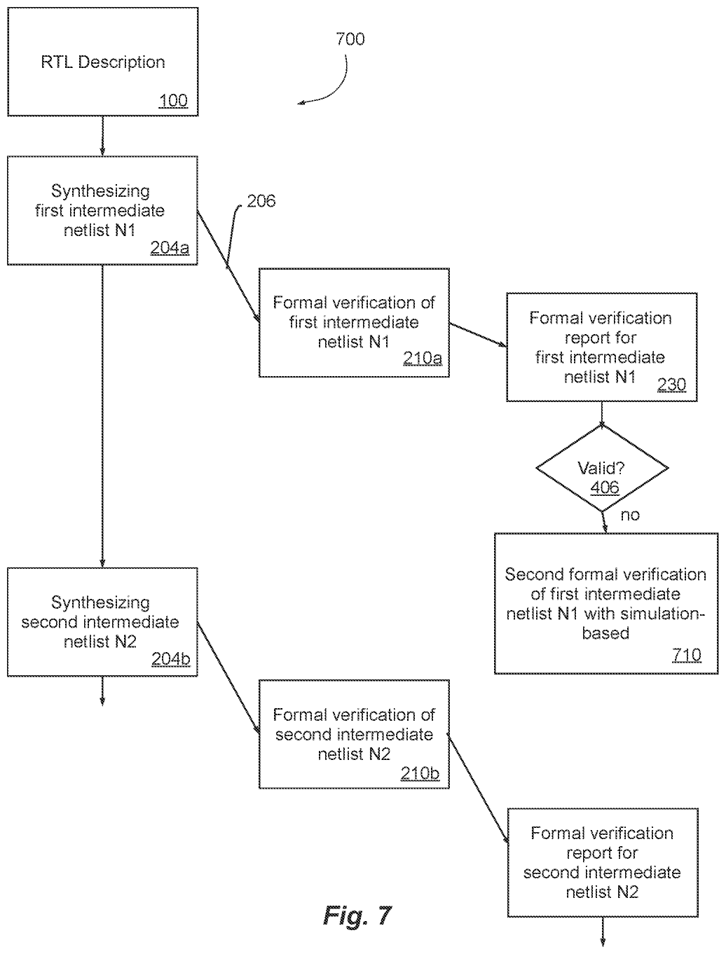

FIG. 4 further depicts an example of the method 400 including modifying 402 an optimization for the RTL description of a non-valid intermediate netlist. As stated above, the verification processes 210a and 210b can return a determination of valid or non-valid for the intermediate netlist. If the intermediate netlist is valid 406, the formal verification process 210a can return an indication 230 of validity, and/or the synthesis 204b and the formal verification process 210b can continue. In one aspect, if the intermediate netlist is invalid 406, the optimization for the RTL description can be modified 402 and a new intermediate netlist can be synthesized from the modified optimization. The formal verification process 210a and 210b can then be launched 206 for the new intermediate netlist. In another aspect, if the intermediate netlist is invalid 406, the designer may change the parameters of the formal verification process 210a and 210b. In another aspect, the designer may pause the synthesis 204b (see description below and FIG. 5). In another aspect, the designer may launch another formal verification process with a different formal verification engine (see description below and FIG. 6). In another aspect, the designer may launch a different formal verification process (see description below and FIG. 7). In another aspect, the designer may do a combination of the above.

FIG. 5 further depicts an example of the method 500 including pausing 504 synthesizing 204b of subsequent intermediate netlist until a previous intermediate netlist is validated by the formal verification process 210a. As indicated above, an intermediate netlist may fail the formal verification process 210a and the designer and/or the synthesis engine 140 (FIG. 1b) may decide to pause 504 the synthesis 204b of further intermediate netlists until the issue is resolved. Synthesizing 204b of the subsequent intermediate netlists may resume (or may be re-started) when the prior intermediate netlist is validated by the formal verification process 210a.

FIG. 6 further depicts an example of the method 600 including launching 206 formal verification processes 210a, 210b, 810a and 810b for an intermediate netlist with two different formal verification engines 150 and 850 in parallel. In one aspect, the designer and/or the synthesis engine 140 (FIG. 1b) may utilize different formal verification engines 150 and 850 for additional confidence in the design, to take advantage of different strengths of the engines, and/or to obtain faster results. In another aspect, as indicated above, an intermediate netlist may fail the formal verification process 210a with one formal verification engine 150 and the designer and/or the synthesis engine 140 (FIG. 1b) may decide to use the different formal verification engine 850.

FIG. 7 further depicts an example of the method 700 including launching 206 a second formal verification process 704 for a non-valid intermediate netlist that is non-valid 406 under a first formal verification process 210a. The second formal verification process 710 can comprise a simulation-based verification process.

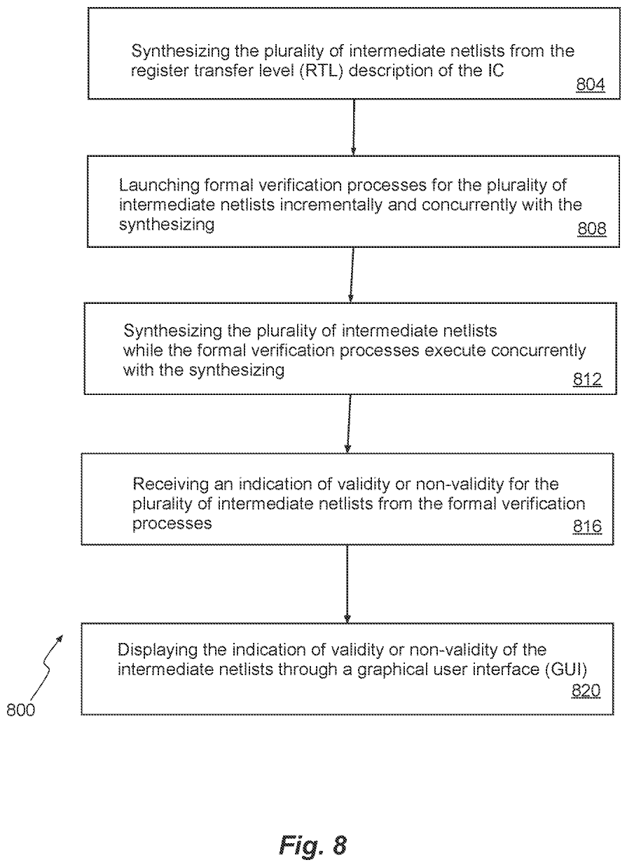

In summary, FIG. 8 depicts an example of a method 800 of designing the IC with concurrent synthesis and formal verification of intermediate and final netlists. The method 800 comprises synthesizing 804 the plurality of intermediate netlists from the register transfer level (RTL) description of the IC. In addition, the method 800 comprises launching 808 the formal verification processes for the plurality of intermediate netlists incrementally and concurrently with the synthesizing 804. In addition, the method 800 comprises continuing synthesizing 812 the plurality of intermediate netlists while the formal verification processes execute concurrently with the synthesizing 812. Furthermore, the method 800 comprises receiving 816 the indication(s) of validity or non-validity for the plurality of intermediate netlists from the formal verification processes.

In another aspect, the present technology, and the synthesis engine 140 (FIG. 1b) and/or formal verification engine 150 (FIG. 1b), can also comprise a machine-readable storage medium having instructions embodied thereon, the instructions when executed by one or more processors, cause the one or more processors to perform a process as described above.

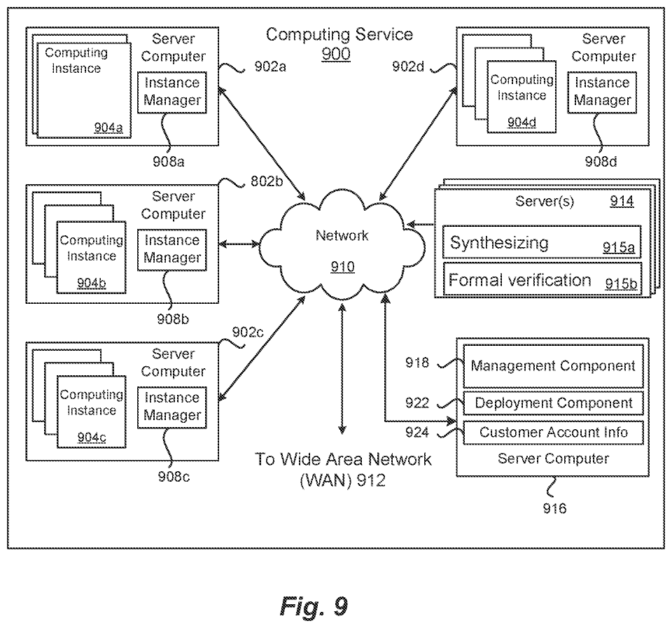

FIG. 9 is a block diagram illustrating an example computing service 900 that may be used to execute and manage a number of computing instances 904a-d upon which the present technology may execute. In particular, the computing service 900 depicted illustrates one environment in which the technology described herein may be used. The computing service 900 may be one type of environment that includes various virtualized service resources that may be used, for instance, to host computing instances 904a-d.

The computing service 900 may be capable of delivery of computing, storage and networking capacity as a software service to a community of end recipients. In one example, the computing service 900 may be established for an organization by or on behalf of the organization. That is, the computing service 900 may offer a “private cloud environment.” In another example, the computing service 900 may support a multi-tenant environment, wherein a plurality of customers may operate independently (i.e., a public cloud environment). Generally speaking, the computing service 900 may provide the following models: Infrastructure as a Service (“IaaS”) and/or Software as a Service (“SaaS”). Other models may be provided. For the IaaS model, the computing service 900 may offer computers as physical or virtual machines and other resources. The virtual machines may be run as guests by a hypervisor, as described further below.

Application developers may develop and run their software solutions on the computing service system without incurring the cost of buying and managing the underlying hardware and software. The SaaS model allows installation and operation of application software in the computing service 900. End customers may access the computing service 900 using networked client devices, such as desktop computers, laptops, tablets, smartphones, etc. running web browsers or other lightweight client applications, for example. Those familiar with the art will recognize that the computing service 900 may be described as a “cloud” environment.

The particularly illustrated computing service 900 may include a plurality of server computers 902a-d. The server computers 902a-d may also be known as physical hosts. While four server computers are shown, any number may be used, and large data centers may include thousands of server computers. The computing service 900 may provide computing resources for executing computing instances 904a-d. Computing instances 904a-d may, for example, be virtual machines. A virtual machine may be an instance of a software implementation of a machine (i.e., a computer) that executes applications like a physical machine. In the example of a virtual machine, each of the server computers 902a-d may be configured to execute an instance manager 908a-d capable of executing the instances. The instance manager 908a-d may be a hypervisor, virtual machine manager (VMM), or another type of program configured to enable the execution of multiple computing instances 904a-d on a single server. Additionally, each of the computing instances 904a-d may be configured to execute one or more applications.

A server 914 may be reserved to execute software components for implementing the present technology or managing the operation of the computing service 900 and the computing instances 904a-d. For example, the server 914 or computing instance may include the synthesizing 915a and/or formal verification processing 915b.

A server computer 916 may execute a management component 918. A customer may access the management component 918 to configure various aspects of the operation of the computing instances 904a-d purchased by a customer. For example, the customer may setup computing instances 904a-d and make changes to the configuration of the computing instances 904a-d.

A deployment component 922 may be used to assist customers in the deployment of computing instances 904a-d. The deployment component 922 may have access to account information associated with the computing instances 904a-d, such as the name of an owner of the account, credit card information, country of the owner, etc. The deployment component 922 may receive a configuration from a customer that includes data describing how computing instances 904a-d may be configured. For example, the configuration may include an operating system, provide one or more applications to be installed in computing instances 904a-d, provide scripts and/or other types of code to be executed for configuring computing instances 904a-d, provide cache logic specifying how an application cache is to be prepared, and other types of information. The deployment component 922 may utilize the customer-provided configuration and cache logic to configure, prime, and launch computing instances 904a-d. The configuration, cache logic, and other information may be specified by a customer accessing the management component 918 or by providing this information directly to the deployment component 922.

Customer account information 924 may include any desired information associated with a customer of the multi-tenant environment. For example, the customer account information may include a unique identifier for a customer, a customer address, billing information, licensing information, customization parameters for launching instances, scheduling information, etc. As described above, the customer account information 924 may also include security information used in encryption of asynchronous responses to API requests. By “asynchronous” it is meant that the API response may be made at any time after the initial request and with a different network connection.

A network 910 may be utilized to interconnect the computing service 900 and the server computers 902a-d, 916. The network 910 may be a local area network (LAN) and may be connected to a Wide Area Network (WAN) 912 or the Internet, so that end customers may access the computing service 900. In addition, the network 910 may include a virtual network overlaid on the physical network to provide communications between the servers 902a-d. The network topology illustrated in FIG. 9 has been simplified, as many more networks and networking devices may be utilized to interconnect the various computing systems disclosed herein.

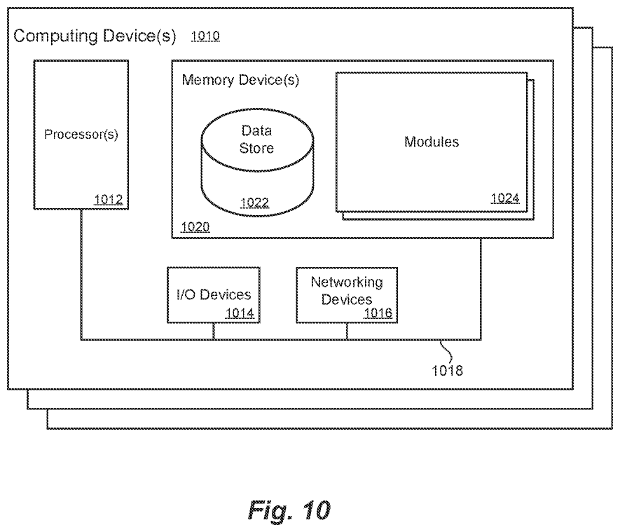

FIG. 10 illustrates a computing device 1010 which may execute the foregoing subsystems of this technology. The computing device 1010 and the components of the computing device 1010 described herein may correspond to the servers and/or client devices described above. The computing device 1010 is illustrated on which a high-level example of the technology may be executed. The computing device 1010 may include one or more processors 1012 that are in communication with memory devices 1020. The computing device may include a local communication interface 1018 for the components in the computing device. For example, the local communication interface may be a local data bus and/or any related address or control busses as may be desired.

The memory device 1020 may contain modules 1024 that are executable by the processor(s) 1012 and data for the modules 1024. For example, the memory device 1020 may include an inflight interactive system module, an offerings subsystem module, a passenger profile subsystem module, and other modules. The modules 1024 may execute the functions described earlier. A data store 1022 may also be located in the memory device 1020 for storing data related to the modules 1024 and other applications along with an operating system that is executable by the processor(s) 1012.

Other applications may also be stored in the memory device 1020 and may be executable by the processor(s) 1012. Components or modules discussed in this description that may be implemented in the form of software using high programming level languages that are compiled, interpreted or executed using a hybrid of the methods.

The computing device may also have access to I/O (input/output) devices 1014 that are usable by the computing devices. An example of an I/O device is a display screen that is available to display output from the computing devices. Other known I/O device may be used with the computing device as desired. Networking devices 1016 and similar communication devices may be included in the computing device. The networking devices 1016 may be wired or wireless networking devices that connect to the internet, a LAN, WAN, or other computing network.

The components or modules that are shown as being stored in the memory device 1020 may be executed by the processor 1012. The term “executable” may mean a program file that is in a form that may be executed by a processor 1012. For example, a program in a higher-level language may be compiled into machine code in a format that may be loaded into a random-access portion of the memory device 1020 and executed by the processor 1012, or source code may be loaded by another executable program and interpreted to generate instructions in a random-access portion of the memory to be executed by a processor. The executable program may be stored in any portion or component of the memory device 1020. For example, the memory device 1020 may be random access memory (RAM), read only memory (ROM), flash memory, a solid-state drive, memory card, a hard drive, optical disk, floppy disk, magnetic tape, or any other memory components.

The processor 1012 may represent multiple processors and the memory 1020 may represent multiple memory units that operate in parallel to the processing circuits. This may provide parallel processing channels for the processes and data in the system. The local interface 1018 may be used as a network to facilitate communication between any of the multiple processors and multiple memories. The local interface 1018 may use additional systems designed for coordinating communication such as load balancing, bulk data transfer, and similar systems.

While the flowcharts presented for this technology may imply a specific order of execution, the order of execution may differ from what is illustrated. For example, the order of two more blocks may be rearranged relative to the order shown. Further, two or more blocks shown in succession may be executed in parallel or with partial parallelization. In some configurations, one or more blocks shown in the flow chart may be omitted or skipped. Any number of counters, state variables, warning semaphores, or messages might be added to the logical flow for purposes of enhanced utility, accounting, performance, measurement, troubleshooting or for similar reasons.

Some of the functional units described in this specification have been labeled as modules, in order to more particularly emphasize their implementation independence. For example, a module may be implemented as a hardware circuit comprising custom VLSI circuits or gate arrays, off-the-shelf semiconductors such as logic chips, transistors, or other discrete components. A module may also be implemented in programmable hardware devices such as field programmable gate arrays, programmable array logic, programmable logic devices or the like.

Modules may also be implemented in software for execution by various types of processors. An identified module of executable code may, for instance, comprise one or more blocks of computer instructions, which may be organized as an object, procedure, or function. Nevertheless, the executables of an identified module need not be physically located together, but may comprise disparate instructions stored in different locations which comprise the module and achieve the stated purpose for the module when joined logically together.

Indeed, a module of executable code may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices. The modules may be passive or active, including agents operable to perform desired functions.

The technology described here can also be stored on a computer readable storage medium that includes volatile and non-volatile, removable and non-removable media implemented with any technology for the storage of information such as computer readable instructions, data structures, program modules, or other data. Computer readable storage media include, but is not limited to, RAM, ROM, EEPROM, flash memory or other memory technology, CD-ROM, digital versatile disks (DVD) or other optical storage, magnetic cassettes, magnetic tapes, magnetic disk storage or other magnetic storage devices, or any other computer storage medium which can be used to store the desired information and described technology.

The devices described herein may also contain communication connections or networking apparatus and networking connections that allow the devices to communicate with other devices. Communication connections are an example of communication media. Communication media typically embodies computer readable instructions, data structures, program modules and other data in a modulated data signal such as a carrier wave or other transport mechanism and includes any information delivery media. A “modulated data signal” means a signal that has one or more of its characteristics set or changed in such a manner as to encode information in the signal. By way of example, and not limitation, communication media includes wired media such as a wired network or direct-wired connection, and wireless media such as acoustic, radio frequency, infrared, and other wireless media. The term computer readable media as used herein includes communication media.

Furthermore, the described features, structures, or characteristics may be combined in any suitable manner in one or more examples. In the preceding description, numerous specific details were provided, such as examples of various configurations to provide a thorough understanding of examples of the described technology. One skilled in the relevant art will recognize, however, that the technology can be practiced without one or more of the specific details, or with other methods, components, devices, etc. In other instances, well-known structures or operations are not shown or described in detail to avoid obscuring aspects of the technology.

Although the subject matter has been described in language specific to structural features and/or operations, it is to be understood that the subject matter defined in the appended claims is not necessarily limited to the specific features and operations described above. Rather, the specific features and acts described above are disclosed as example forms of implementing the claims. Numerous modifications and alternative arrangements can be devised without departing from the spirit and scope of the described technology.

What is claimed is:

1. A method for designing an integrated circuit (IC), comprising:
synthesizing a plurality of intermediate netlists from a register transfer level (RTL) description of the IC;
launching formal verification processes for the plurality of intermediate netlists concurrently with the synthesizing;
synthesizing the plurality of intermediate netlists while the formal verification processes execute concurrently with the synthesizing; and
receiving an indication of validity or non-validity for the plurality of intermediate netlists from the formal verification processes.

2. The method in accordance with claim 1, wherein:
synthesizing the plurality of intermediate netlists comprises synthesizing a first intermediate netlist;
launching the formal verification processes comprises launching a formal verification process for the first intermediate netlist; and
synthesizing the plurality of intermediate netlists sequentially comprises synthesizing a second intermediate netlist while the formal verification process executes concurrently for the first intermediate netlist.

3. The method in accordance with claim 1, wherein synthesizing and launching formal verification processes further comprise:
synthesizing a first intermediate netlist; and
launching a formal verification process for the first intermediate netlist concurrently while synthesizing a second intermediate netlist.

4. The method in accordance with claim 1, wherein launching the formal verification processes further comprises:
launching a formal verification process for a subsequent intermediate netlist and comparing the subsequent intermediate netlist with a prior intermediate netlist.

5. The method in accordance with claim 1, wherein launching the formal verification processes further comprises:
launching formal verification processes for at least two separate intermediate netlists in parallel.

6. The method in accordance with claim 1, further comprising:
proving that the RTL description is formally equivalent to a final netlist using the intermediate netlists by proving that the intermediate netlists are valid.

7. The method in accordance with claim 1, further comprising:
modifying an optimization for the RTL description in response to a non-valid intermediate netlist that is indicated as non-valid during the formal verification process in order to define a modified optimization for the RTL description;
synthesizing a new intermediate netlist from the modified optimization for the RTL description; and
launching a formal verification process for the new intermediate netlist.

8. The method in accordance with claim 1, wherein the intermediate netlists have different transformations comprising at least one of: retiming or optimizations.

9. The method in accordance with claim 1, further comprising:
pausing synthesizing of a subsequent intermediate netlist until a previous intermediate netlist is validated by the formal verification process; and
resuming synthesizing the subsequent intermediate netlists when the prior intermediate netlist is validated by the formal verification process.

10. The method in accordance with claim 1, wherein launching the formal verification process further comprises:
entering a command to a synthesis engine capable of performing synthesizing, in order to launch the formal verification process for the intermediate netlist to begin.

11. The method in accordance with claim 1, wherein the synthesizing and the formal verification processes are performed by separate synthesis and formal verification engines, respectively, and wherein the synthesis engine launches the formal verification processes for the formal verification engine.

12. The method in accordance with claim 1, further comprising:
sending the intermediate netlists sequentially from a synthesis engine to a formal verification engine.

13. The method in accordance with claim 1, further comprising:
specifying formal verification parameters for the formal verification processes selected from the group comprising at least one of:
mode of formal verification or not formal verification;
a selection of a formal verification engine;
incremental dumps of intermediate netlists;
frequency of dumps of intermediate netlists; or
use of naming conventions.

14. The method in accordance with claim 1, wherein launching the formal verification processes further comprises:
launching formal verification processes for an intermediate netlist with two different formal verification engines in parallel.

15. The method in accordance with claim 1, further comprising:
launching a second formal verification process for a non-valid intermediate netlist that is non-valid under a first formal verification process, wherein the second formal verification process comprises a simulation-based verification process.

16. A method for designing an integrated circuit (IC), comprising:
synthesizing a plurality of intermediate netlists from a register transfer level (RTL) description of the IC;
launching formal verification processes for the plurality of intermediate netlists concurrently with the synthesizing;
synthesizing the plurality of intermediate netlists while the formal verification processes execute concurrently with the synthesizing; and
proving that the RTL description is formally equivalent to a final netlist formed of the intermediate netlists by proving that the all the intermediate netlists are valid.

17. The method in accordance with claim 16, wherein launching the formal verification processes further comprises:
launching formal verification processes for at least two separate intermediate netlists in parallel.

18. A machine-readable storage medium having instructions embodied thereon, the instructions when executed by one or more processors, cause the one or more processors to perform a process comprising:
synthesizing a plurality of intermediate netlists sequentially from a register transfer level (RTL) description of the IC;
launching formal verification processes for the plurality of intermediate netlists concurrently with the synthesizing;
continuing synthesizing the plurality of intermediate netlists while the formal verification processes execute concurrently with the synthesizing; and
receiving an indication of validity or non-validity of the plurality of intermediate netlists from the formal verification process.

19. The machine-readable storage medium of claim 18, further comprising:
displaying the indication of validity or non-validity of the intermediate netlists through a graphical user interface (GUI).

20. The machine-readable storage medium of claim 18, further comprising:
launching formal verification processes for at least two separate intermediate netlists in parallel.
